(19) United States
(12) Patent Application Publication
(10) Pub. No.: US 2026/0301811 A1
(43) Pub. Date: Oct. 1, 2026

(54) SEMICONDUCTOR DEVICE WITH CONTENT ADDRESSABLE MEMORY UNITS

(71) Applicant: TAIWAN SEMICONDUCTOR MANUFACTURING COMPANY LTD., HSINCHU (TW)

(72) Inventor: KATHERINE H. CHIANG, NEW TAIPEI CITY (TW)

(21) Appl. No.: 19/095,080

(22) Filed: Mar. 31, 2025

(51) Int. Cl. G11C 15/04; H10B 51/20; H10B 51/30

(52) U.S. Cl. CPC G11C 15/046; H10B 51/20; H10B 51/30

(57) ABSTRACT

A semiconductor device is provided. The semiconductor device includes a plurality of word lines extending along a first direction, a plurality of match lines extending along a second direction, a plurality of content addressable memory (CAM) units arranged in an array, and a plurality of word line drivers. The array is divided into a plurality of sub-arrays extending in a plane formed by the first direction and the second direction. Each word line driver is connected to the word lines of an individual sub-array of the array, and configured to control the CAM units of the corresponding sub-array to be configured in a first configuration or a second configuration. Each CAM unit is configured to store first data in the first configuration and second data in the second configuration, and the first data and the second data have different bit numbers.

### BACKGROUND

Many modern electronic devices contain electronic memory configured to store data. As technoloGx advances at a rapid pace, engineers work to make memory devices smaller, yet more complex to improve and develop electronic devices that are more efficient, more reliable, and have more capabilities. Individual memory cells may be vertically stacked in three-dimensional (3D) memory, allowing for more a greater bit density, and thus more efficient electronic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 is a three-dimensional (3D) view of a memory device, in accordance with some embodiments of the present disclosure.

FIG. 2 is a cross-sectional view (a top view or a layout) of the sub-arrays in FIG. 1 along cross-section A-A, in accordance with some embodiments of the present disclosure.

FIG. 3 is a searching/mapping unit, in accordance with some embodiments of the present disclosure.

FIG. 4A is a schematic illustrating the searching/mapping unit of FIG. 3 in a ternary CAM configuration, in accordance with some embodiments of the present disclosure.

FIG. 4B is a schematic illustrating the searching/mapping unit of FIG. 3 in a bit-by-bit comparison configuration, in accordance with some embodiments of the present disclosure.

FIG. 5 is a semiconductor device, in accordance with some embodiments of the present disclosure.

FIG. 6 shows a flow chart illustrating the various in-memory computing (IMC) tasks are performed in a pipeline manner, in accordance with some embodiments of the present disclosure.

FIG. 7A is a semiconductor device, in accordance with some embodiments of the present disclosure.

FIG. 7B illustrate the stages of the query operation performed in the semiconductor device of FIG. 7A, in accordance with some embodiments of the present disclosure.

FIG. 8A is a schematic illustrating the searching/mapping unit of FIG. 3 functioning as a Boolean function unit, in accordance with some embodiments of the present disclosure.

FIG. 8B is a table illustrating truth tables and stored data for a logic gate implemented in the searching/mapping unit of FIG. 8A, in accordance with some embodiments of the present disclosure.

FIG. 9 is a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as "beneath", "below", "above", "upper", "lower", "left", "right" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being "connected to" or "coupled to" another element, it may be directly connected to or coupled to the other element, or intervening elements may be present.

According to the embodiments, a semiconductor device is provided. The semiconductor device includes a controller and a memory formed by multiple content addressable memory (CAM) units arranged in an array. The array of CAM units is divided into multiple sub-arrays, and each sub-array is dynamically reconfigurable to support multiple functions, even to establish computation pipeline all-in-memory. The controller is configured to program formats of width and depth of search data for each sub-array. Each sub-array is configured into a ternary CAM configuration or a bit-by-bit comparison configuration by the controller, allowing searches to be arranged in a pipelined manner or to perform Boolean functions.

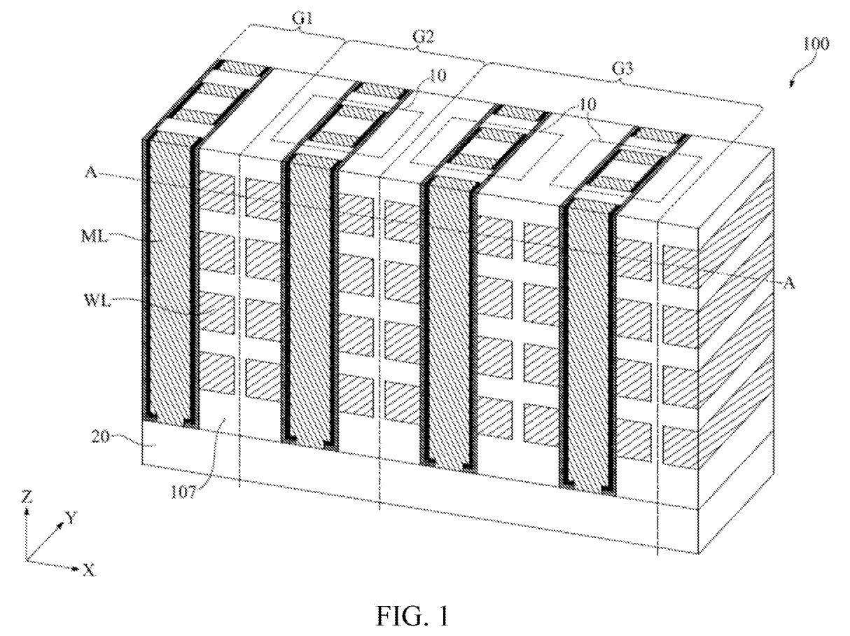

FIG. 1 is a three-dimensional (3D) view of a memory device 100, in accordance with some embodiments of the present disclosure. The memory device 100 is a content addressable memory (CAM) device. The memory device 100 includes multiple CAM units (or cells) 10 arranged in an array.

In some embodiments, each CAM unit 10 has no more than two ferroelectric transistors for storing data. Furthermore, these ferroelectric transistors may be referred to as ferroelectric memory elements. Because each CAM unit 10 includes no more than two ferroelectric transistors, the memory device 100 has a smaller footprint and/or are less expensive in terms of power consumption and cost per bit in comparison to the CAM units that each included eight transistors including a static random-access memory (SRAM) cell with approximately six transistors. Furthermore, since the ferroelectric transistors are non-volatile, the memory device 100 can be used for a wider range of applications in which power is not constantly provided.

In the memory device 100, the word lines WL extend along the Y-direction, and match lines ML extend along the Z-direction. The CAM units 10 of the memory device 100 are divided into multiple sub-arrays (e.g., sub-devices or slices), and the sub-arrays extend along a plane formed by the Y-direction and the Z-direction. Each sub-array is configured to compare input search data against an array of stored data. Furthermore, each sub-array allows for a fast bitwise comparison between a large number of predetermined search results and a specific data query, and provides an address at which a match occurs. In the embodiment of FIG. 1, the sub-arrays G1, G2 and G3 are shown. In some embodiments, the memory device 100 may include more or fewer sub-arrays. In each of the sub-arrays G1, G2 and G3, multiple word lines WL are stacked on a semiconductor substrate 20 along the Z-direction, and the word lines WL are separated from each other on the Z-direction by the isolation structure 107. Furthermore, each of the sub-arrays G1, G2 and G3 has dynamic reconfigurability, e.g., ternary CAM configuration or bit-by-bit comparison configuration (or non-ternary CAM configuration), to support multiple functions.

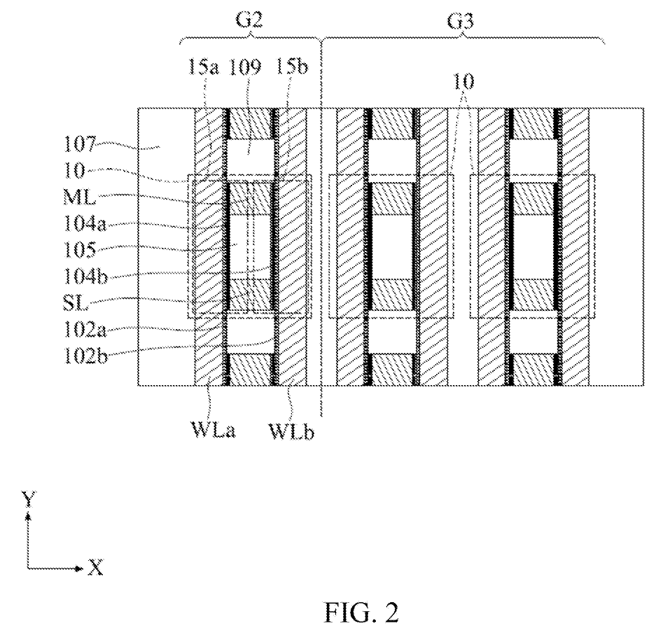

FIG. 2 is a cross-sectional view (a top view or a layout) of the sub-arrays G2 and G3 in FIG. 1 along cross-section A-A, in accordance with some embodiments of the present disclosure. Each CAM unit 10 includes a pair of ferroelectric storage elements (or transistors) 15a and 15b adjacent to each other. The ferroelectric memory element 15a includes a gate coupled to a word line WLa, a source coupled to a source line SL, and a drain coupled to a match line ML. The ferroelectric memory element 15b includes a gate coupled to a word line WLb, a source coupled to the source line SL, and a drain coupled to the match line ML. In other words, in each CAM unit 10, the drains of the ferroelectric memory elements 15a and 15b are coupled to the same match line ML, and the sources of the ferroelectric memory elements 15a and 15b are coupled to the same source line SL. In other words, the ferroelectric memory elements 15a and 15b in the same CAM unit 10 share the same match line ML and the same source line SL.

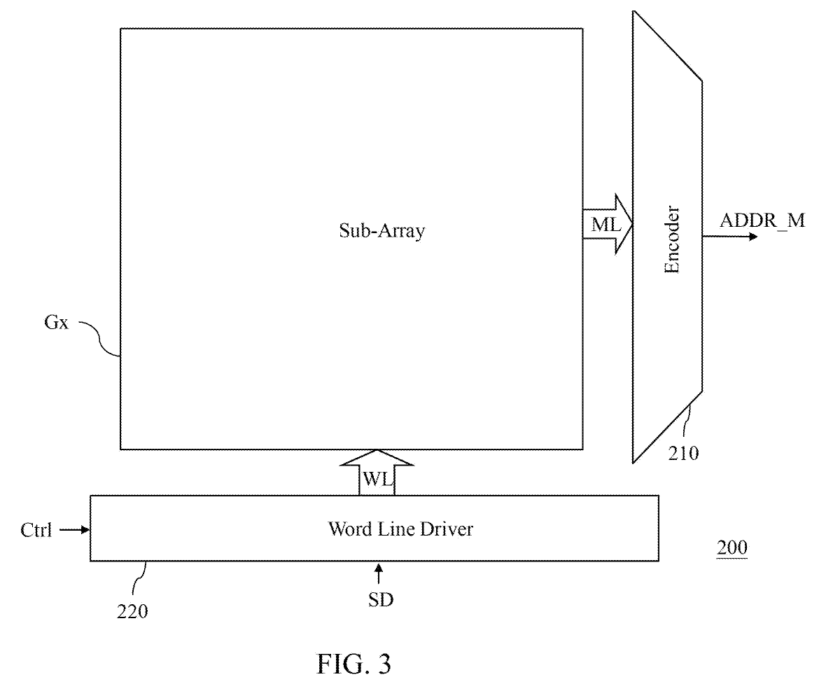

The word lines WLa and WLb extend in the Y-direction. The word line WLa is disposed along a first sidewall of an outer insulating layer 109. The word line WLb is disposed along a second sidewall of the outer insulating layer 109. In some embodiments, the word lines WLa and WLb are coupled to a word line driver 220 of FIG. 3 and are configured to respectively search the ferroelectric memory elements 15a and 15b based on the search voltages of the word lines WLa and WLb. The word lines WLa and WLb are further configured to apply a data signal to program threshold voltages of the ferroelectric memory elements 15a and 15b, respectively. In some embodiments, the ferroelectric memory elements 15a and 15b define a CAM unit 10, and the word line WLa is complementary to the word line WLb. i.e., the word lines WLa and WLb form a word line pair WL. Furthermore, the word lines WLa and WLb are configured to apply a data signal to program a data state of the CAM unit 10. In some embodiments, the word lines WLa and WLb are unpaired word lines, and the word lines WLa and WLb are configured to apply a data signal to program a data state of the corresponding ferroelectric memory elements 15a and 15b, respectively.

A ferroelectric layer 102a is disposed along an inner sidewall of the word line WLa, and a ferroelectric layer 102b is disposed along an inner sidewall of the word line WLb. In some embodiments, the ferroelectric layers 102a and 102b have a non-volatile remaining polarization that can correspond to a stored data state. In some embodiments, the ferroelectric layer 102a is configured to store a data state of the ferroelectric memory element 15a, and the ferroelectric layer 102b is configured to store a data state of the ferroelectric memory element 15b. In embodiments where the ferroelectric memory elements 15a and 15b jointly define a CAM unit 10, the data state of the CAM unit 10 is dependent on the data states of both ferroelectric memory elements 15a and 15b.

A channel layer 104a is disposed along an inner sidewall of the ferroelectric layer 102a. A channel layer 104b is disposed along an inner sidewall of the ferroelectric layer 102b. The source line SL is sandwiched between the channel layers 104a and 104b, and is configured to provide an output signal to the match line ML if a search query does not match the data state(s) of the ferroelectric memory elements 15a and/or 15b. The match line ML is also sandwiched between the channel layers 104a and 104b, and is configured to assert the match signals. An inner insulating layer 105 is sandwiched between the match line ML and the source line SL and is configured to provide electrical isolation between the match line ML and the source line SL. An isolation structure 107 is disposed along a sidewall of the match line ML and a sidewall of the source line SL that face away from the inner insulating layer 105. The isolation structure 107 provides isolation between ferroelectric memory elements 15a and 15b in the Y-direction. In some embodiments, the isolation structure 107 contacts opposing surfaces of the channel layer 104a and opposing surfaces of the channel layer 104b. In some embodiments, the ferroelectric layers 102a and 102b extend continuously in the Y- direction.

In some embodiments, the isolation structure 107 may be or otherwise comprise, for example, silicon oxycarbide, silicon oxycarbonitride, aluminum oxide, hafnium dioxide, lanthanum oxide, some other suitable oxide-doped or metal oxide material(s), or some other suitable material(s). In some embodiments, the isolation structure 107 comprises a different material than that of the inner insulating layer 105. In some embodiments, the inner insulating layer 105 and the outer insulating layer 109 may be or otherwise comprise, for example, an oxide or some other suitable material(s). In some embodiments, the channel layers 104a and 104b may be or otherwise comprise, for example, indium gallium zinc oxide, indium zinc oxide, indium tin oxide, indium tungsten oxide, zinc tin oxide, zinc oxide, gallium oxide, tin oxide, or some other suitable oxide semiconductor material(s). In some embodiments, the ferroelectric layers 102a and 102b may be or otherwise comprise, for example, a ferroelectric material (hafnium zirconium oxide, hafnium oxide, or some other suitable ferroelectric material(s). In some embodiments, the ferroelectric material may be further doped with lanthanum, cerium, silicon, aluminum, or some other suitable material(s) to improve ferroelectricity. In some embodiments, the word lines WLa and WLb are conductive and may be or otherwise comprise, for example, tungsten, titanium nitride, aluminum copper, or some other suitable material(s). In some embodiments, the match line ML and the source line SL are conductive and may be or otherwise comprise, titanium nitride, tungsten, ruthenium, or some other suitable material(s).

FIG. 3 is a searching/mapping unit 200, in accordance with some embodiments of the present disclosure. The searching/mapping unit 200 includes the sub-array Gx of the memory device 100 of FIG. 1, an encoder 210 and a word line driver 220 for the sub-array Gx. The sub-array Gx includes multiple CAM units 10. The CAM units 10 are arranged in rows and columns in a three-dimensional array. Furthermore, one or more searching/mapping units 200 can be assigned as a group to perform one searching/mapping operation. In some embodiments, the peripheral circuits of the sub-array Gx, e.g., the encoder 210 and the word line driver 220, are formed under the sub-array Gx, i.e., the peripheral circuits are implemented in CMOS under Array (CuA), achieving high density.

The word line driver 220 is configured to provide the search voltages (or signals) corresponding to the search data SD to the sub-array Gx through the word lines WL. Once the data stored in the CAM units 10 arranged in the same row of the sub-array Gx is equal to the search data SD, the corresponding match line ML is asserted. According to the one or more asserted match lines ML, the encoder 210 is configured to provide an address ADDR_M for the search data SD.

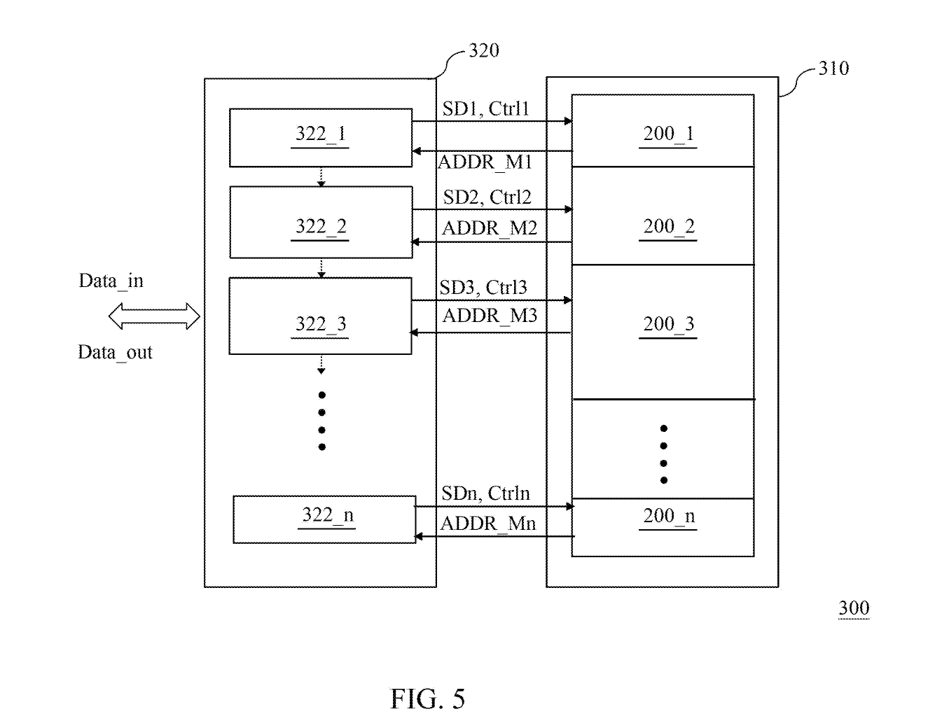

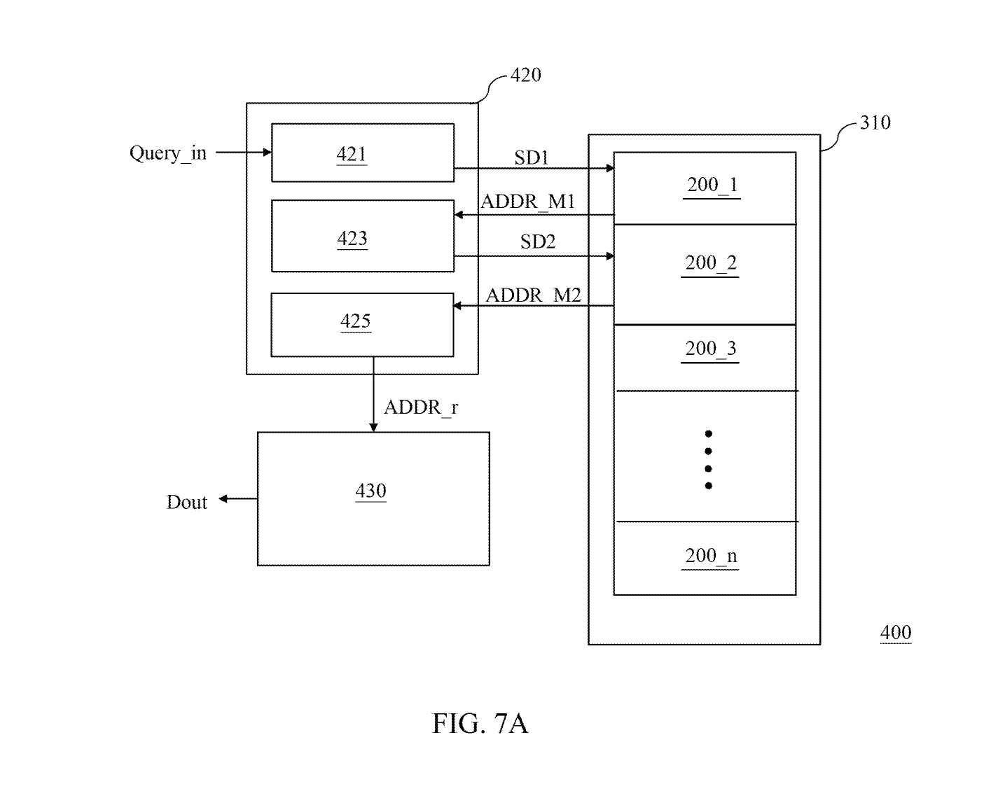

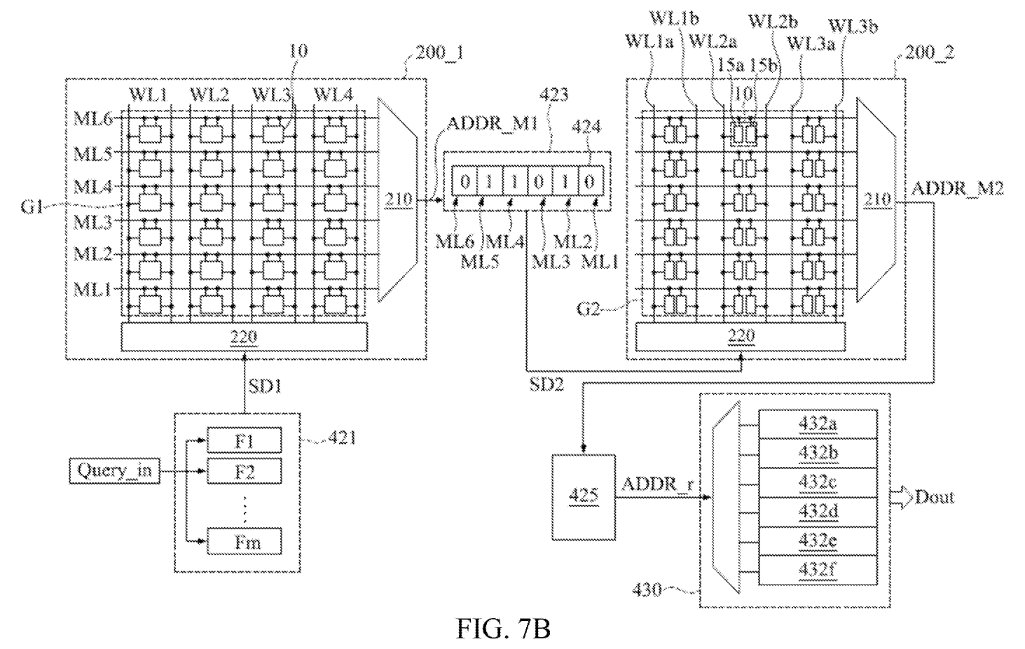

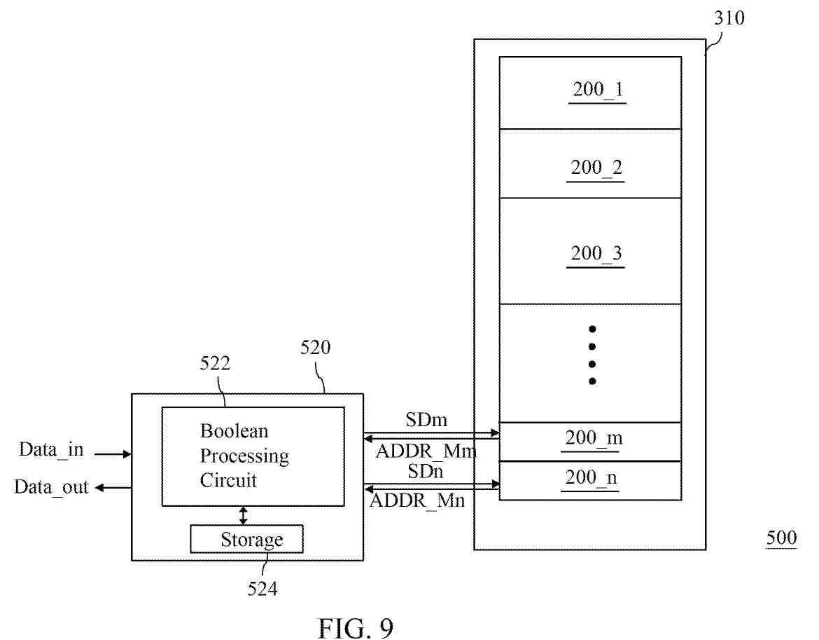

A control signal Ctrl from a controller (e.g., 320 of FIG. 5, 420 of FIG. 7A, and 520 of FIG. 9) is provided to the word line driver 220. When the control signal Ctrl indicates that the sub-array Gx is configured into a ternary CAM configuration, the word line driver 220 is configured to provide search voltages to the sub-array Gx through multiple pairs of word lines WL according to the search data SD. In such embodiment, the bit number of the search data SD is equal to the pair number of the word lines WL. Furthermore, when the control signal Ctrl indicates that the sub-array Gx is configured into the bit-by-bit comparison configuration, the word line driver 220 is configured to provide the search voltages to the sub-array Gx through multiple unpaired word lines WL according to the search data SD. In such embodiment, the bit number of the search data SD is equal to the number of the unpaired word lines WL.

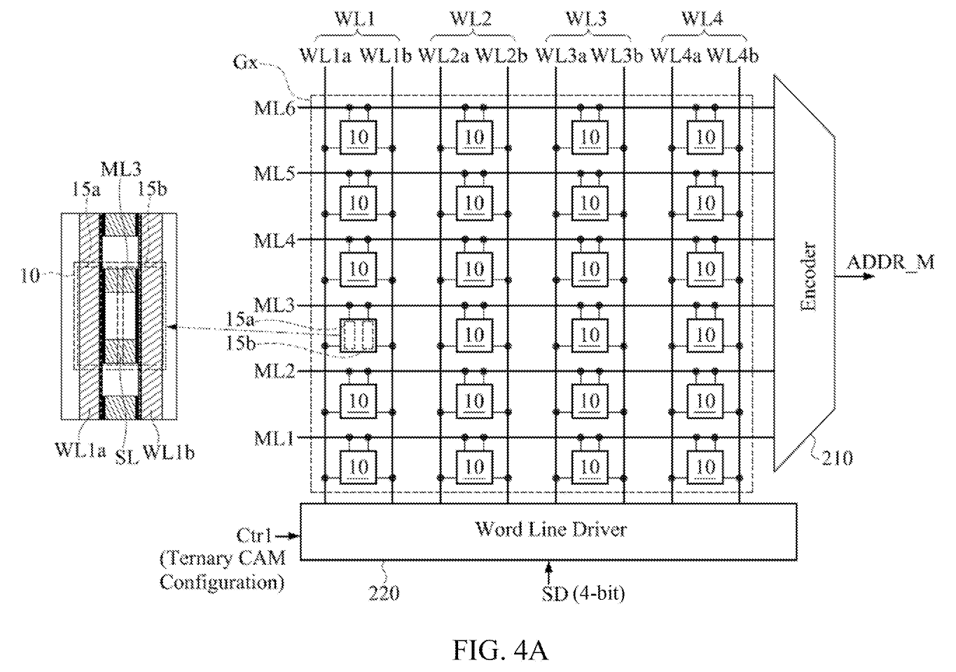

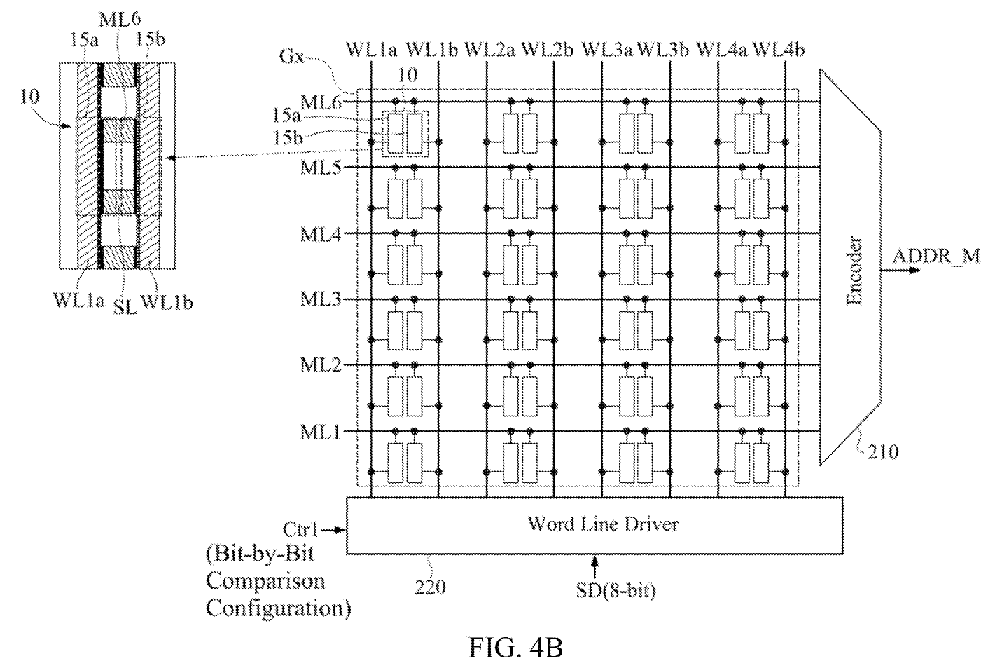

FIG. 4A is a schematic illustrating the searching/mapping unit 200 of FIG. 3 in a ternary CAM configuration, in accordance with some embodiments of the present disclosure. For convenience of explanation, the CAM units 10 of the sub-array Gx are represented by rows and columns in the plane.

In the embodiment of FIG. 4A, each CAM unit 10 includes a pair of ferroelectric memory elements (e.g., the ferroelectric memory elements 15a and 15b of FIG. 2), which cooperatively store a data state for that respective CAM unit 10. To simplify the explanation, the source lines SL of the CAM units 10 in the sub-array Gx are omitted in FIG. 4A. Furthermore, the sub-array Gx is configured into the ternary CAM configuration through dynamic signal assignment with the control signal Ctrl, eliminating the need for additional hardware. In the ternary CAM configuration, each word line pair represents a bit of the search data SD in the query. In this embodiment, the search data SD has 4 bits, and the word line driver 220 is configured to provide four pairs of word lines. Hereinafter, they are called word line pairs WL1 to WL4.

The word line pairs WL1 through WL4 extend along the respective columns and are coupled to the gates of ferroelectric memory elements 15a and 15b of the respective columns. For example, the word line pair WL1 is coupled to a first column of CAM units 10, and includes the word lines WL1a and WL1b. The word line WL1a is complementary to the word line WL1b. The word line WL1a is coupled to the ferroelectric memory elements 15a in the first column of CAM units 10, and the word line WL1b is coupled to the ferroelectric memory elements 15b in the first column of CAM units 10. The match lines ML1 through ML6 extend along the respective rows and are coupled to the drains of the ferroelectric memory elements 15a and 15b of the respective rows. For example, the match line ML1 is coupled to the ferroelectric memory elements 15a and 15b in a first row of CAM units 10, and the match line ML3 is coupled to the ferroelectric memory elements 15a and 15b in a third row of CAM units 10. Furthermore, the source lines SL (not shown) are coupled to the sources of the ferroelectric memory elements 15a and 15b in the respective rows.

A word line driver 220 is configured to provide voltage biases to the word line pairs WL1 through WL4 during read and write operations, and a source line driver (not shown) and a match line driver (not shown) correspondingly provide voltage biases to the source lines SL and the match lines ML1 through ML6 during read operations and/or write operations. The match lines ML1 through ML6 are coupled to the encoder 210.

In some embodiments, the data state of the CAM unit 10 is based on threshold voltages of the ferroelectric memory elements 15a and 15b. For example, the data state for the CAM unit 10 is programmed by setting the threshold voltages of the ferroelectric memory elements 15a and 15b of the CAM unit 10 according to a pre-established convention. For example, the data state “0” of a given CAM unit 10 can correspond to the ferroelectric memory element 15a of the CAM unit having a first threshold voltage and the ferroelectric memory element 15b of the CAM unit having a second voltage threshold. Furthermore, the data state “1” of the given CAM unit 10 can “flip” these threshold voltages, e.g., the data state “1” correspond to the ferroelectric memory element 15a having the second threshold voltage and the ferroelectric memory element 15b having the first threshold voltage. Moreover, the data state “X” (e.g., a logical "don't care") of the CAM unit 10 can correspond to the ferroelectric memory elements 15a and 15b of the CAM unit having the same threshold voltage. Therefore, the CAM unit 10 is configured to store1-bit data in the ternary CAM configuration. By programming the CAM units 10 according to such a convention, predetermined search results can be written into the sub-array Gx such that each CAM unit 10 stores a separate data bit (data state). It will be appreciated that any predetermined search results could also be written to the sub-array Gx, and this writing can occur prior to search queries being provided and/or can be updated during or after search queries are provided.

After these predetermined search results have been written to the sub-array Gx, a search query can be provided to the sub-array Gx by appropriately biasing the match lines ML1 through ML6, the word line pairs WL1 through WL4 and/or the source lines SL. When the search query matches the predetermined search result of a given row, the match line ML of the corresponding row is asserted to indicate a match has occurred for the data of that row. Furthermore, the match lines ML whose data does not match the search query are de-asserted. In response to the match line of the given row being asserted, the encoder 210 is configured to output an address ADDR_M which corresponds to the row being asserted.

In some embodiments, during a query operation, a parallel search is performed by the word line driver 220 and the match lines ML1 through ML6 such that the CAM units 10 are searched simultaneously. In some embodiments, when multiple rows of CAM units 10 bitwise match the search query, the address ADDR_M of only the first row of CAM units 10 to assert a match signal is outputted (e.g., the match line ML1 is asserted when more than one row of CAM units 10 match the search query). In some embodiments, one or more sub-arrays of the memory device 100 in FIG. 1 other than the sub-array Gx may be configured to use the address ADDR_M outputted by the sub-array Gx as a search query for the one or more sub-arrays. In some embodiments, the sub-arrays of the memory device 100 may be searched simultaneously. In further embodiments, the memory device 100 may be configured to search the one or more sub-arrays and output a match address that is subsequently processed by other circuit.

FIG. 4B is a schematic illustrating the searching/mapping unit 200 of FIG. 3 in a bit-by-bit comparison configuration, in accordance with some embodiments of the present disclosure. For convenience of explanation, the CAM units 10 of the sub-array Gx are represented by rows and columns in the plane.

In the embodiment of FIG. 4B, the ferroelectric memory elements 15a and 15b of each CAM unit 10 respectively store a data state. In other words, the ferroelectric memory elements 15a and 15b can be considered as two sub-units of the CAM unit 10. To simplify the explanation, the source lines SL in the sub-array Gx are omitted in FIG. 4B. Furthermore, the sub-array Gx is configured into the bit-by-bit comparison configuration through dynamic signal assignment with the control signal Ctrl, eliminating the need for additional hardware. In the bit-by-bit configuration, each word line represents a bit of the search data SD in the query. In this embodiment, the search data SD has 8 bits, and the word line driver 220 is configured to provide the search voltages in eight word lines WL1a through WL4a and WL1b through WL4b.

The word lines WL1a through WL4a extend along the respective columns and are coupled to the gates of ferroelectric memory elements 15a of the respective columns, and the word lines WL1b through WL4b extend along the respective columns and are coupled to the gates of ferroelectric memory elements 15b of the respective columns. For example, the word line WL1a is coupled to a first column of ferroelectric memory elements 15a, and the word line WL1b is coupled to the first column of ferroelectric memory elements 15b. The word line WL1a is independent of the word line WL1b. The match lines ML1 through ML6 extend along the respective rows and are coupled to the drains of the ferroelectric memory elements 15a and 15b of the respective rows. For example, the match line ML1 is coupled to the ferroelectric memory elements 15a and 15b in a first row of CAM units 10, and the match line ML2 is coupled to the ferroelectric memory elements 15a and 15b in a second row of CAM units 10. Furthermore, the source lines SL (not shown) are coupled to the sources of the ferroelectric memory elements 15a and 15b of the respective rows.

The word line driver 220 provides voltage biases to the word lines WL1a through WL4a and WL1b through WL4b during read and write operations, and a source line driver (not shown) and a match line driver (not shown) correspondingly provide voltage biases to the source lines SL and match lines ML1 through ML6 during read operations and/or write operations. The match lines ML1 through ML6 are coupled to the encoder 210.

In some embodiments, the data state of the ferroelectric memory element 15a or 15b is based on its threshold voltage. For example, the data state for each ferroelectric memory element is programmed by setting the threshold voltages of the ferroelectric memory elements 15a and 15b of the CAM unit 10 according to a pre-established convention. For example, the data state “1” of a given ferroelectric memory element 15a or 15b can correspond to the ferroelectric memory element 15a or 15b with a specific threshold voltage. Furthermore, the data state “X” (e.g., a logical "don't care") of the given ferroelectric memory element 15a or 15b can correspond to the ferroelectric memory element 15a or 15b without the specific threshold voltage. Therefore, the CAM unit 10 is configured to store 2-bit data in the bit-by-bit comparison configuration.

By programming the ferroelectric memory elements 15a and 15b according to such a convention, predetermined search results can be written into the sub-array Gx such that each ferroelectric memory element 15a/15b stores a separate data bit (data state). It will be appreciated that any predetermined search results could also be written to the sub-array Gx, and this writing can occur prior to search queries being provided and/or can be updated during or after search queries are provided.

After these predetermined search results have been written to the sub-array Gx, a search query can be provided to the sub-array Gx by appropriately biasing the match lines ML1 through ML6, the word lines WL1a through WL4a and WL1b through WL4b and/or the source lines SL. When the search query matches the predetermined search result of a given row, the match line ML of the corresponding row is asserted to indicate a match has occurred for the data of that row. Furthermore, the match lines ML whose data does not match the search query are de-asserted. In response to the match line of the given row being asserted, the encoder 210 is configured to output an address ADDR_M which corresponds to the row being asserted.

In some embodiments, during a query operation, a parallel search is performed by the word line driver 220 and the match lines ML1 through ML6 such that the ferroelectric memory elements 15a and 15b are searched simultaneously. In some embodiments, when multiple rows of the ferroelectric memory elements 15a and 15b bitwise match the search query, the address ADDR_M of only the first row of CAM units 10 to assert a match signal is outputted (i.e., the match line ML1 is asserted when more than one row of CAM units 10 match the search query). In some embodiments, one or more sub-arrays of the memory device 100 in FIG. 1 other than the sub-array Gx may be configured to use the address ADDR_M outputted by the sub-array Gx as a search query for the one or more sub-arrays. In some embodiments, the sub-arrays of the memory device 100 may be searched simultaneously. In further embodiments, the memory device 100 may be configured to search the one or more sub-arrays and output a match address that is subsequently processed by other circuit.

FIG. 5 is a semiconductor device 300, in accordance with some embodiments of the present disclosure. The semiconductor device 300 includes a memory 310 and a controller 320 for searching the memory 310. In some embodiments, the semiconductor device 300 is an integrated circuit (IC). The memory 310 includes multiple searching/mapping units 200_1 through 200_n. As described above, each of the searching/mapping units 200_1 through 200_n includes a respective sub-array of the memory device 100. For example, the searching/mapping unit 200_1 includes the sub-array G1 of the memory device 100, the corresponding encoder, and the corresponding drivers for the word lines WL, the source lines SL, and the match lines ML. The searching/mapping unit 200_2 includes the sub-array G2 of the memory device 100, the corresponding encoder, and the corresponding drivers for the word lines WL, the source lines SL, and the match lines ML. In some embodiments, the sub-arrays of the searching/mapping units 200_1 through 200_n have the same number of CAM units 10. In some embodiments, the sub-arrays of the search/mapping units 200_b to 200_n have different numbers of CAM units 10. Furthermore, each sub-array of the searching/mapping units 200_1 through 200_n is configured into a ternary CAM configuration or a bit-by-bit comparison configuration according to a respective control signal Ctrl.

The controller 320 is configured to perform multiple query operations with the searching/mapping units 200_1 through 200_n. The controller 320 includes multiple processing circuits 322_1 through 322_n. Each of the processing circuits 322_1 through 322_n is configured to provide a respective search data SD to the corresponding searching/mapping unit 200 for searching the corresponding sub-array and then obtain the corresponding address ADDR_M. In some embodiments, the controller 320 is formed under the memory device 100.

In some embodiments, each of the processing circuits 322_1 through 322_n is configured to perform an individual search operation, i.e., the search operations are independent of each other. For example, the processing circuit 322_1 is configured to provide the search data SD1 from the input data Data_in to the searching/mapping unit 200_1 for search the sub-array G1, and obtain the address ADDR_M1 corresponding to the search data SD1 to provide the output data Data_out. Similarly, the processing circuit 322_2 is configured to provide the search data SD2 from the input data Data_in to the searching/mapping unit 200_2 for search the sub-array G2, and obtain the address ADDR_M2 corresponding to the search data SD2 to provide the output data Data_out, and so on.

In some embodiments, the processing circuits 322_1 through 322_n are configured to perform an in-memory computing (IMC), i.e., the operations for each IMC task are related. For example, the processing circuit 322_1 is configured to provide the search data SD1 from the input data Data_in to the searching/mapping unit 200_1 for search the sub-array G1, and then obtain the address ADDR_M1 corresponding to the search data SD1. After obtaining the address ADDR_M1, the processing circuit 322_1 is configured to perform the logical processing operation or data retrieval operation of the IMC, and provide the operation result to the processing circuit 322_2. Next, the processing circuit 322_2 is configured to provide the search data SD2 to the searching/mapping unit 200_2 according to the operation result from the processing circuit 322_1 for search the sub-array G2, and obtain the address ADDR_M2 corresponding to the search data SD2. Similarly, after obtaining the address ADDR_M2, the processing circuit 322_2 is configured to perform the logical processing operation or data retrieval operation of the IMC, and provide the operation result to the processing circuit 322_3. Subsequent processing circuits will perform similar operations until the IMC task is completed.

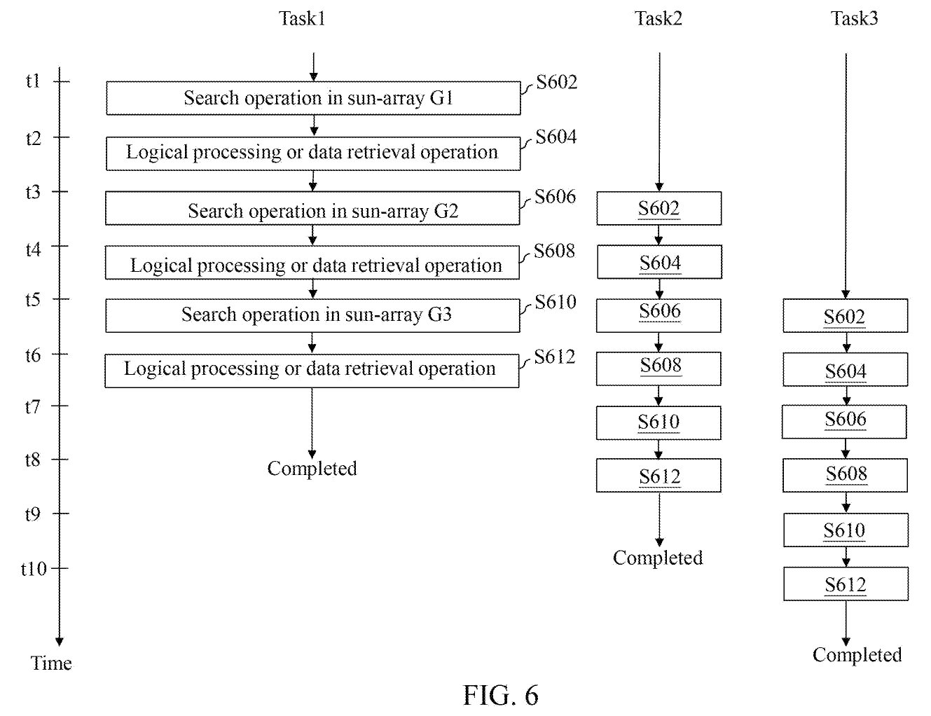

FIG. 6 shows a flow chart illustrating the various IMC tasks are performed in a pipeline manner, in accordance with some embodiments of the present disclosure. In the embodiment of FIG. 6, three IMC tasks Task1, Task2 and Task3 are shown, and each ICM task includes the operations S602 through S612.

In operation S602, the processing circuit 322_1 is configured to provide the search data SD1 to perform the search operation in the sub-array G1 of the searching/mapping unit 200_1. In operation S604, the processing circuit 322_1 is configured to perform the logical processing operation or data retrieval operation of the current IMC task based on the search results of the operation S602, e.g., the address ADDR_M1 from the sub-array G1. In operation S606, the processing circuit 322_2 is configured to provide the search data SD2 to perform the search operation in the sub-array G2 of the searching/mapping unit 200_2. In operation S608, the processing circuit 322_2 is configured to perform the logical processing operation or data retrieval operation of the current IMC task based on the search results of the operation S606, e.g., the address ADDR_M2 from the sub-array G2. In operation S610, the processing circuit 322_3 is configured to provide the search data SD3 to perform the search operation in the sub-array G3 of the searching/mapping unit 200_3. In operation S612, the processing circuit 322_3 is configured to perform the logical processing operation or data retrieval operation of the current IMC task based on the search results of the operation S610, e.g., the address ADDR_M3 from the sub-array G3. After the operation S612 is performed, the computing result of the current IMC task is obtained.

First, at time t1, operation S602 of the first task Task1 is performed. At time t2, operation S604 of the first task Task1 is performed. At time t3, operation S606 of the first task Task1 and operation S602 of the second task Task2 are performed. Thus, the first task Task1 and the second task Task2 are performed simultaneously in the memory 310. At time t4, operation S608 of the first task Task1, and operation S604 of the second task Task2 are performed. At time t5, operation S610 of the first task Task1, operation S606 of the second task Task2, and operation S602 of the third task Task3 are performed. Thus, the first task Task1, the second task Task2, and the third task Task3 are performed simultaneously in the memory 310. At time t6, operation S612 of the first task Task1, operation S608 of the second task Task2, and operation S604 of the third task Task3 are performed. At time t7, operation S610 of the second task Task2 and operation S606 of the third task Task3 are performed, and the first task Task1 has been completed. At time t8, operation S612 of the second task Task2 and operation S608 of the third task Task3 are performed. At time t9, operation S610 of the third task Task3 is performed, and the second task Task2 has been completed. At time t10, operation S612 of the third task Task3 is performed, and then the third task Task3 has been completed.

FIG. 7A is a semiconductor device 400, in accordance with some embodiments of the present disclosure. The semiconductor device 400 includes a memory 310 and a controller 420 for accessing the memory 310. In some embodiments, the semiconductor device 400 is an IC. As described above, the memory 310 includes multiple searching/mapping units 200_1 through 200_n, and each of the searching/mapping units 200_1 through 200_n includes a respective sub-array of the memory device 100. In some embodiments, the sub-arrays of the searching/mapping units 200_1 through 200_n have the same number of CAM units 10. In some embodiments, the sub-arrays of the search/mapping units 200_1 to 200_n have different numbers of CAM units 10. Furthermore, each sub-array of the searching/mapping units 200_1 through 200_n is configured into a ternary CAM configuration or a bit-by-bit comparison configuration according to a respective control signal Ctrl. To simplify the explanation, the control signals Ctrl of the search/mapping units 200_1 to 200_n are omitted in FIG. 7A.

The controller 420 is configured to perform a query operation (or a pattern matching operation) for the data Query_in with the searching/mapping units 200_1 and 200_2. The controller 420 includes a feature extraction circuit 421, a processing circuit 423, and a retrieval circuit 425. In some embodiments, the controller 420 is formed. In some embodiments, the controller 420 and the controller 320 of FIG. 5 are implemented in the same IC for various operations of the memory 310.

FIG. 7B illustrate the stages of the query operation performed in the semiconductor device 400 of FIG. 7A, in accordance with some embodiments of the present disclosure. Referring to FIGS. 7A and 7B, the feature extraction circuit 421 is configured to extract the features F1 through Fm from the data Query_in, and sequentially provide each of the features F1 through Fm as the search data SD1 to the searching/mapping unit 200_1.

In the embodiment of FIGS. 7A and 7B, the sub-array G1 of the searching/mapping unit 200_1 is configured into a ternary CAM configuration according to the control signal Ctrl (not shown). Therefore, each CAM unit 10 in the sub-array G1 can be programmed to the data state "0", "1", or "X", e.g., 1-bit data, as shown in FIG. 4A. In response to the search data SD1, the word line driver 220 of the searching/mapping unit 200_1 is configured to provide the corresponding word line pairs WL1 through WL4 to the sub-array G1. Next, the encoder 210 of the searching/mapping unit 200_1 is configured to output an address ADDR_M1 to the processing circuit 423, and the address ADDR_M1 represents which row of the CAM units 10 (i.e., which match line ML) is asserted (i.e., the data stored in the row of the CAM units 10 match the feature). For example, in a first period, the feature F1 is provided as the search data SD to search the sub-array G1, and the match line M2 is asserted and the address ADDR_M1 corresponding to the match line M2 is provided to the processing circuit 423. The processing circuit 423 includes a register 424 having six bits, and each bit corresponds to an individual match line of the sub-array G1. In response to the address ADDR_M1 indicating the match line M2 is asserted, the second bit of the register 424 is set to a high logic "1", e.g., the second bit of the register 424 is flagged. Next, in a second period, the feature F2 is provided as the search data SD to search the sub-array G1, and no match line is asserted. Thus, no flag is set in the register 424. The feature extraction circuit 421 is configured to continuously provide the remaining features to the searching/mapping unit 200_1 until the last feature Fm is provided to the searching/mapping unit 200_1.

The address ADDR_M1 corresponding to each of the features F1 through Fm is recombined in the register 424 to obtain the necessary features (or important features) of the data Query_in. After searching the features F1 through Fm, the bits of the register 424 corresponding to the match lines ML2, ML4 and ML5 of the sub-array G1 are flagged in the processing circuit 423. In other words, the data stored in the rows of the CAM units 10 corresponding to the match lines ML2, ML4 and ML5 match some of the features F1 through Fm.

Next, the processing circuit 423 is configured to provide the value of the register 424 as the search data SD2 to the searching/mapping unit 200_2. In the embodiment of FIGS. 7A and 7B, the sub-array G2 of the searching/mapping unit 200_2 is configured into a bit-by-bit comparison configuration according to the control signal Ctrl (not shown). Therefore, each of the ferroelectric memory elements 15a and 15b in the CAM unit 10 of the sub-array G2 can be programmed to the data state "1", while the unprogrammed data state is "X", as shown in FIG. 4B. In the bit-by-bit configuration, each word line WLa/WLb represents a bit of the search data SD2 in the query. In this embodiment, the search data SD2 has 6 bits corresponding to the value of the register 424 (e.g., SD="011010"), and the word line driver 220 provides six word lines WL1a through WL3a and WL1b through WL3b. For example, the word line WL1a corresponds to a least significant bit (LSB) of the search data SD2, and the word line WL3b corresponds to a most significant bit (MSB) of the search data SD2.

In response to the search data SD2, the word line driver 220 of the searching/mapping unit 200_2 is configured to provide the corresponding word lines WL1a through WL3a and WL1b through WL3b to the sub-array G2, Next, the encoder 210 of the searching/mapping unit 200_2 is configured to output an address ADDR_M2 to the retrieval circuit 425, and the address ADDR_M2 represents which row of the ferroelectric memory elements 15a and 15b (i.e., which match line ML) is asserted (i.e., the data stored in the row of the ferroelectric memory elements 15a and 15b match the search data SD2). The retrieval circuit 425 is configured to provide a retrieved address ADDR_r to a retrieval database 430. The retrieval database 430 includes multiple data regions 432a through 432f, and each of the data regions 432a through 432f is configured to store individual classified data. In response to the retrieved address ADDR_r, the retrieval database 430 is configured to provide the retrieved data Dout from the data region corresponding to the retrieved address ADDR_r. Therefore, a high-dimensional indexing, classification or data retrieval operation, is performed in-memory.

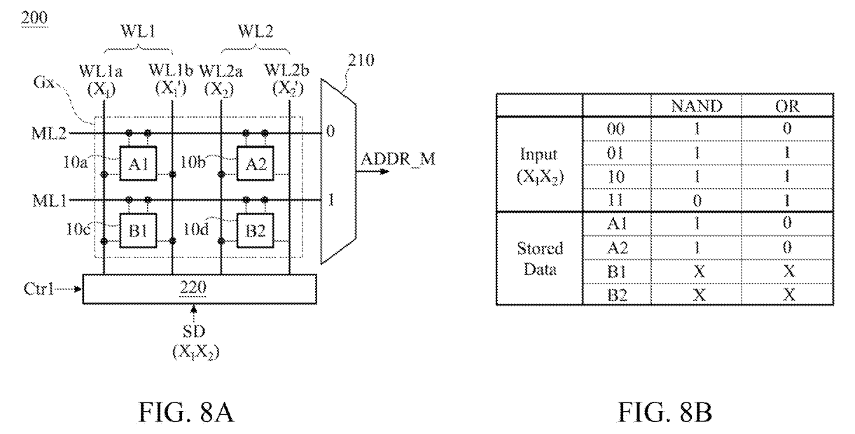

FIG. 8A is a schematic illustrating the searching/mapping unit 200 of FIG. 3 functioning as a Boolean function unit, in accordance with some embodiments of the present disclosure. For convenience of explanation, the CAM units 10 of the sub-array Gx are represented by rows and columns in the plane. Furthermore, the searching/mapping unit 200 is configured in a ternary CAM configuration in response to the control signal Ctrl.

FIG. 8B is a table illustrating truth tables and stored data for a logic gate implemented in the searching/mapping unit 200 of FIG. 8A, in accordance with some embodiments of the present disclosure.

Referring to FIGS. 8A and 8B, the sub-array Gx includes the CAM units 10a, 10b, 10c and 10d. The CAM units 10a and 10c share the word line pair WL1 comprising the word lines WL1a and WL1b, and the CAM units 10b and 10d share the word line pair WL2 comprising the word lines WL2a and WL2b. Furthermore, the CAM units 10a and 10b share the match line ML2, and the CAM units 10c and 10d share the match line ML1. The search data SD comprises a first input X₁ and a second input X₂ for the NAND or OR gate. The word line driver 220 is configured to provide the search voltage in the word line pair WL1 according to the first input X₁, and provide the search voltage in the word line pair WL2 according to the second input X₂. In some embodiments, the search voltage of the word line WL1a corresponds to the first input X₁, and the search voltage of the word line WL1b corresponds to the complement of the first input X₁. Similarly, the search voltage of the word line WL2a corresponds to the second input X₂, and the search voltage of the word line WL2b corresponds to the complement of the second input X₂.

When the sub-array Gx is configured to perform a Boolean function of the NAND gate, the data state A1 of the CAM unit 10a and the data state A2 of the CAM unit 10b are programmed to "1", and the data state B1 of the CAM unit 10c and the data state B2 of the CAM unit 10d are programmed to "X" (e.g., a logical "don't care"). In response to the search data SD with a value of "00", "01" or "10", the match line ML1 is asserted to indicate a match for the data states B1 and B2, and the encoder 210 is configured to output the address ADDR_M with a value of "1". In response to the search data SD with a value of "11", the match line ML2 is asserted to indicate a match for the data states A1 and A2, and the encoder 210 is configured to output the address ADDR_M with a value of "0".

When the sub-array Gx is configured to perform a Boolean function of the OR gate, the data state A1 of the CAM unit 10a and the data state A2 of the CAM unit 10b are programmed to "0", and the data state B1 of the CAM unit 10c and the data state B2 of the CAM unit 10d are programmed to "X" (e.g., a logical "don't care"). In response to the search data SD with a value of "11", "01" or "10", the match line ML1 is asserted to indicate a match for the data states B1 and B2, and the encoder 210 is configured to output the address ADDR_M with a value of "1". In response to the search data SD with a value of "00", the match line ML2 is asserted to indicate a match for the data states A1 and A2, and the encoder 210 is configured to output the address ADDR_M with a value of "0".

FIG. 9 is a semiconductor device 500, in accordance with some embodiments of the present disclosure. The semiconductor device 500 includes a memory 310 and a controller 520 for accessing the memory 310. In some embodiments, the semiconductor device 500 is an IC. As described above, the memory 310 includes multiple searching/mapping units 200_1 through 200_n, and each of the searching/mapping units 200_1 through 200_n includes a respective sub-array of the memory device 100. In some embodiments, the sub-arrays of the searching/mapping units 200_1 through 200_n have the same number of CAM units 10. In some embodiments, the sub-arrays of the search/mapping units 200_1 to 200_n have different numbers of CAM units 10. Furthermore, each sub-array of the searching/mapping units 200_1 through 200_n is configured into a ternary CAM configuration or a bit-by-bit comparison configuration according to a respective control signal Ctrl.

The controller 520 is configured to perform a Boolean operation for the input data Data_in to provide the output data Data_out. In the embodiment of FIG. 9, the searching/mapping units 200_m and 200_n are configured into the ternary CAM configuration and function as the Boolean function units. In some embodiments, the searching/mapping units 200_m and 200_n are configured to perform a Boolean function of the same logic gate. In some embodiments, the searching/mapping units 200_m and 200_n are configured to perform various Boolean functions of different logic gates. The controller 520 includes a Boolean processing circuit 522, and a storage 524. In some embodiments, the controller 520 is formed under the memory device 100. In some embodiments, the controller 520, the controller 420 of FIG. 7A, and the controller 320 of FIG. 5 are implemented in the same IC for various operations of the memory 310.

The Boolean processing circuit 522 is configured to using the searching/mapping units 200_m and 200_n to perform one or more Boolean operations of the input data Data_in by providing the search data SDm and SDn and receiving the addresses ADDR_Mm and address ADDR_Mn. In some embodiments, the result of the Boolean operation is temporarily stored in the storage 524 to serve as the input of the subsequent Boolean operation. In the embodiment of FIG. 9, the searching/mapping units 200_m and 200_n offer higher density than standard logic cells, and their Boolean operations can be reprogrammed, enhancing implementation flexibility.

The controller (e.g., 320 of FIG. 5, 420 of FIG. 7A, and 520 of FIG. 9) of the memory 310 is configured to program formats of width and depth of search data, or reconfigure between ternary-CAM and necessary component check, or to arrange pipeline. Furthermore, complex computing-in-memory operations, which are equivalent to generalized pattern matching or some Boolean functions, are achieved through compositions of multiple searching/mapping steps enabled by the CAM’s dynamic reconfigurability.

According to the embodiments, a semiconductor device is provided based on the 3D High Density Non-Volatile CAM (with CMOS under Array). A memory device including an array of CAM units 10 is divided into multiple sub-arrays, and each sub-array is dynamically reconfigurable to support multiple functions, even to establish computation pipeline all-in-memory. The sub-arrays are configured to support more general queries whose search results are the “keys” for downstream queries or data retrieval. The sequence of query computations can all be achieved in-memory for various applications, such as recommender systems, data mining, medical diagnostics, and so on.

According to some embodiments, a semiconductor device is provided. The semiconductor device includes a plurality of word lines extending along a first direction, a plurality of match lines extending along a second direction that is substantially perpendicular to the first direction, a plurality of content addressable memory (CAM) units arranged in an array, and a plurality of word line drivers. The array is divided into a plurality of sub-arrays extending in a plane formed by the first direction and the second direction. Each of the word line drivers is connected to the word lines of an individual sub-array of the array, and configured to control the CAM units of the corresponding sub-array to be configured in a first configuration or a second configuration. Each of the CAM units is configured to store first data in the first configuration and second data in the second configuration, and the first data and the second data have different bit numbers.

According to some embodiments, a semiconductor device is provided. The semiconductor device includes a memory and a controller. The memory includes a plurality of searching/mapping units. Each of the searching/mapping units includes a plurality of content addressable memory (CAM) units arranged in an array, a word line driver connected to the CAM units of the array through a plurality of word lines extending along a first direction and configured to control the CAM units to be configured in a first configuration or a second configuration according to a control signal, and provide a plurality of search voltages corresponding to search data to the CAM units through the word lines, and an encoder connected to the CAM units of the array through a plurality of match lines extending along a second direction that is substantially perpendicular to the first direction, and configured to provide an address to indicate which match line is asserted. The controller includes a plurality of processing circuits, each configured to provide the search data and the control signal to an individual searching/mapping unit. Each of the CAM units is configured to store first data in the first configuration and second data in the second configuration, and the first data and the second data have different bit numbers.

According to some embodiments, a method for forming and operating a memory comprising a plurality of content addressable memory (CAM) is provided. The method includes: arranging a plurality of word lines of the memory extending along in a first direction; arranging a plurality of match lines of the memory extending along in a second direction that is substantially perpendicular to the first direction; dividing the array into a plurality of sub-arrays extending in a plane formed by the first direction and the second direction; providing a plurality of word line drivers; and controlling the CAM units of each of the sub-arrays to be configured in a first configuration or a second configuration through the word line driver connected to the corresponding sub-array. Each of the word line drivers is connected to the word lines of an individual sub-array of the array. Each of the CAM units is configured to store first data in the first configuration and second data in the second configuration, and the first data and the second data have different bit numbers. The sub-arrays have different numbers of CAM units.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of word lines extending along a first direction;
a plurality of match lines extending along a second direction that is substantially perpendicular to the first direction;
a plurality of content addressable memory (CAM) units arranged in an array, wherein the array is divided into a plurality of sub-arrays extending in a plane formed by the first direction and the second direction; and
a plurality of word line drivers, wherein each of the word line drivers is connected to the word lines of an individual sub-array of the array, and configured to control the CAM units of the corresponding sub-array to be configured in a first configuration or a second configuration,
wherein each of the CAM units is configured to store first data in the first configuration and second data in the second configuration, and the first data and the second data have different bit numbers.

2. The semiconductor device of claim 1, further comprising:
a plurality of encoders, wherein each of the encoders is connected to the match lines of an individual sub-array of the array, and configured to provide an address to indicate which match line is asserted.

3. The semiconductor device of claim 1, wherein each of the CAM units includes a first ferroelectric memory element and a second ferroelectric memory element sharing the same match line.

4. The semiconductor device of claim 3, wherein in each of the CAM units, a first word line coupled to the first ferroelectric memory element is complementary to a second word line coupled to the second ferroelectric memory element in the first configuration, and the first and second ferroelectric memory elements cooperatively store the first data with one bit.

5. The semiconductor device of claim 3, wherein in each of the CAM units, a first word line coupled to the first ferroelectric memory element is independent of a second word line coupled to the second ferroelectric memory element in the second configuration, and each of the first and second ferroelectric memory elements stores one bit of the second data.

6. The semiconductor device of claim 1, wherein the sub-arrays have different numbers of CAM units.

7. A semiconductor device, comprising:
a memory, comprising a plurality of searching/mapping units, wherein each of the searching/mapping units comprising:
a plurality of content addressable memory (CAM) units arranged in an array;
a word line driver, connected to the CAM units of the array through a plurality of word lines extending along a first direction, and configured to control the CAM units to be configured in a first configuration or a second configuration according to a control signal, and provide a plurality of search voltages corresponding to search data to the CAM units through the word lines; and
an encoder, connected to the CAM units of the array through a plurality of match lines extending along a second direction that is substantially perpendicular to the first direction, and configured to provide an address to indicate which match line is asserted; and
a controller, comprising:
a plurality of processing circuits, each configured to provide the search data and the control signal to an individual searching/mapping unit,
wherein each of the CAM units is configured to store first data in the first configuration and second data in the second configuration, and the first data and the second data have different bit numbers.

8. The semiconductor device of claim 7, wherein each of the CAM units includes a first ferroelectric memory element and a second ferroelectric memory element sharing the same match line.

9. The semiconductor device of claim 8, wherein in each of the CAM units, the search voltage of a first word line coupled to the first ferroelectric memory element is complementary to the search voltage of a second word line coupled to the second ferroelectric memory element in the first configuration, and the first and second ferroelectric memory elements cooperatively store the first data with one bit.

10. The semiconductor device of claim 8, wherein in each of the CAM units, the search voltage of a first word line coupled to the first ferroelectric memory element is independent of the search voltage of a second word line coupled to the second ferroelectric memory element in the second configuration, and each of the first and second ferroelectric memory elements stores one bit of the second data.

11. The semiconductor device of claim 7, wherein the CAM units of the array is formed over a semiconductor structure, and the word line driver, the encoder and the controller are formed under the CAM units of the array.

12. The semiconductor device of claim 7, wherein the searching/mapping units have different numbers of CAM units.

13. The semiconductor device of claim 7, wherein a first processing circuit of the processing circuits is configured to provide a first search data to a first searching/mapping unit of the searching/mapping units and obtain the address corresponding to the first search data from the first searching/mapping unit, and a second processing circuit of the processing circuits is configured to provide a second search data according to the address to a second searching/mapping unit of the searching/mapping units.

14. The semiconductor device of claim 13, wherein when the second processing circuit of the processing circuits is configured to provide the second search data to the second searching/mapping unit, the first processing circuit of the processing circuits is configured to provide a next first search data to the first searching/mapping unit.

15. The semiconductor device of claim 7, wherein the controller further comprises:
a feature extraction circuit, configured to extract a plurality of features from query data, and sequentially provide each of the features as a first search data to a first searching/mapping unit of the searching/mapping units,
wherein a first processing circuit of the processing circuits is configured to provide a second search data according to the address corresponding to the first search data from the first searching/mapping unit to a second searching/mapping unit of the searching/mapping units.

16. The semiconductor device of claim 15, wherein the first processing circuit comprises a register, and each bit of the register corresponds to an individual match line of the first searching/mapping unit, wherein when one of the match lines of the first searching/mapping unit is asserted, the bit of the register corresponding to the one of the match lines is flagged by the first processing circuit.

17. The semiconductor device of claim 7, wherein the controller further comprises:
a Boolean processing circuit configured to use at least one of the searching/mapping units to perform a specific Boolean operation,
wherein each of the CAM units of the at least one of the searching/mapping units is configured to store the first data in the first configuration, and the first data has a ternary data state.

18. A method for forming and operating a memory comprising a plurality of content addressable memory (CAM) units arranged in an array, comprising:
arranging a plurality of word lines of the memory extending along in a first direction;
arranging a plurality of match lines of the memory extending along in a second direction that is substantially perpendicular to the first direction;
dividing the array into a plurality of sub-arrays extending in a plane formed by the first direction and the second direction;
providing a plurality of word line drivers, wherein each of the word line drivers is connected to the word lines of an individual sub-array of the array; and
controlling the CAM units of each of the sub-arrays to be configured in a first configuration or a second configuration through the word line driver connected to the corresponding sub-array,
wherein each of the CAM units is configured to store first data in the first configuration and second data in the second configuration, and the first data and the second data have different bit numbers,
wherein the sub-arrays have different numbers of CAM units.

19. The method of claim 18, comprising:
providing a plurality of encoders, wherein each of the encoders is connected to the match lines of an individual sub-array of the array, and configured to provide an address to indicate which match line is asserted.

20. The method of claim 18, wherein each of the CAM units includes a first ferroelectric memory element and a second ferroelectric memory element sharing the same match line, wherein the first and second ferroelectric memory elements cooperatively store the first data with one bit in the first configuration, and each of the first and second ferroelectric memory elements stores one bit of the second data in the second configuration.
